(19) United States
(12) Patent Application Publication
(10) Pub. No.: US 2008/0282828 A1
(43) Pub. Date: Nov. 20, 2008

(54) POINTING A PLURALITY OF ELEMENTS IN THE SAME DIRECTION

(75) Inventor: Russell K. Jones, Manhattan Beach, CA (US)

Correspondence Address: CANADY & LORTZ LLP - BOEING, 2540 HUNTINGTON DRIVE, SUITE 205, SAN MARINO, CA, 91108, US

(73) Assignee: The Boeing Company, Chicago, IL (US)

(21) Appl. No.: 11/751,018

(22) Filed: May 19, 2007

(51) Int. Cl. G05G 1/00; H01L 31/042; H01Q 1/00

(52) U.S. Cl. 74/471 R; 136/244; 343/720

(57) ABSTRACT

Mechanical systems and methods are disclosed for pointing a plurality of elements in an array in any direction within a near-hemispherical field of view without pointing the entire array as a single unit. A fixed frame and an adjuster frame disposed substantially parallel to and offset from each other are each coupled by universal joints to carriers for a plurality of elements. One or more drive mechanisms are used to move the adjuster frame relative to the fixed frame to produce coordinated pointing of the pointing axes of the plurality of elements. The systems and methods can be used in a variety of applications including pointing of solar concentrator receivers or antennas.

### BACKGROUND OF THE INVENTION

1. Field of the Invention

This invention relates to mechanical pointing mechanisms. Particularly, this invention relates mechanical pointing mechanisms for controlling solar energy systems, such as used by ground-based solar stations.

2. Description of the Related Art

Solar energy has the potential to provide a significant fraction of all electrical power needs with a clean and virtually endless energy source. Development and commercialization of solar energy systems has been underway for half a century and the ability of solar energy solutions to provide power at costs competitive with fuel-burning solutions has steadily improved. However, contemporary solar energy systems are still too expensive to enjoy widespread commercial use.

Photovoltaic (PV) cells are the preferred building block in solar energy systems for generating electricity from the sun since they convert sunlight directly to electricity. (Alternately, solar thermal systems are known to employ a much more complex heat engine where a working fluid heated by the sun, coupled to a generator that produces electricity.) However, some of the most efficient photovoltaic cells are also the most expensive. These devices can produce electricity at efficiencies of approximately 28% under direct solar illumination today and up to approximately 39% under concentrated sunlight. It has been recognized by many in the solar power industry that concentrator systems, in which optical elements focus energy on much smaller cells, can provide overall system solutions that are lower in installed cost per watt than competing conventional flat direct solar illumination panels. Because these systems can reduce the required area of expensive semiconductor solar cells by a factor of a hundred or more, these high concentration photovoltaic (HCPV) solar power systems are the one of the better prospects for becoming economically competitive with electricity generated from other sources. In addition, the economics for concentrator systems permit the use of the highest efficiency cells. In turn, this allows concentrated solar power systems to produce significantly more power per unit of surface area, potentially satisfying a larger fraction of the electrical load of a site within a limited land or rooftop space.

In order to maximize efficiency, a solar power system must also provide a way to track the sun. All conventional tracking approaches are based on tracking of arrays of concentrator cells. In general, there are three conventional mechanical systems to provide tracking, “pan and tilt”, “azimuth and elevation”, and “lazy susan”. These terms refer to the basic mechanism for pointing a full array of solar cells. In a three-axis coordinate system (x, y, z) in which the z axis is the vertical axis, the “pan and tilt” approach rotates the entire array around the x and y axes. The “azimuth and elevation” method rotates the array around the z axis and one of the other axes (x or y). The “lazy susan” approach may be viewed as a variant of the “azimuth and elevation” type in which the elevation rotation is performed on rows of elements linked mechanically to an elevation drive motor mechanism.

One primary disadvantage of the conventional solutions is that they require large-scale movements of all of the elements of the array. With the “pan and tilt” and “azimuth and elevation” approaches, the entire panel is steered to point at the sun and both suffer particularly from the fact that they present large surfaces to the wind and require significant increases in structural cost and motor cost to withstand these loads, or else (as is more typically the case) the systems have limited ability to remain operable in strong winds and must instead be positioned in “safe mode” wherein a low profile is exposed to the wind. The “lazy susan” approach is pursued by some implementers primarily to reduce these unfavorable wind loads, but still requires the entire array to be rotated.

Finally, another significant disadvantage of the conventional tracking approaches is that they are undesirable for use in many important commercial applications of solar energy such as residential rooftops and portable systems, because of the structure and appearance necessary for pointing large two-axis tracking arrays.

In view of the foregoing, there is a need in the art for apparatuses and methods for implementing concentrated solar power systems. Particularly, there is a need for improved systems and methods for pointing arrays of solar cells in solar power systems. Further, there is a need for such pointing systems and methods to operate without requiring large scale movements of an array of solar cells. In addition, there is a need for such pointing systems and methods to operate with unobstrusive structures for portable and/or terrestrial applications, such as on residential rooftops. These and other needs are met by the present invention as detailed hereafter.

### SUMMARY OF THE INVENTION

Mechanical systems and methods are disclosed for pointing a plurality of elements in an array in any direction within a near-hemispherical field of view without pointing the entire array as a single unit. A fixed frame and an adjuster frame disposed substantially parallel to and offset from each other are each coupled by universal joints to carriers for a plurality of optical elements. One or more drive mechanisms are used to move the adjuster frame relative to the fixed frame to produce coordinated pointing of the pointing axes of the plurality of optical elements. The systems and methods can be used in a variety of applications including pointing of solar concentrator receivers or antennas.

A typical embodiment of the invention comprises an apparatus for coordinated pointing of elements including a plurality of elements each having a pointing axis and each being attached to a carrier, a fixed frame including a first universal joint coupled to the carrier for each of the plurality of elements, an adjuster frame disposed substantially parallel to the fixed frame and including a second universal joint coupled to the carrier offset from the first universal joint for each of the plurality of elements, and at least one drive mechanism to move the adjuster frame relative to the fixed frame to produce coordinated pointing of the plurality of elements.

In some embodiments, the plurality of elements comprise photovoltaic cells in a solar power system. For example, the solar cells may be high concentration photovoltaic cells. In other embodiments, the plurality of elements may be antenna elements in an antenna array.

Typically, the fixed frame is disposed between the adjuster frame and the plurality of elements. The carrier may comprise a rod coupled to both the first universal joint and the second universal joint and substantially parallel to the pointing axis. The one or more drive mechanisms may comprise an azimuth drive and an elevation drive. In addition, the azimuth drive and the elevation drive may each include a jack screw. Furthermore, the first and second universal joints may each include a rotary joint and a clevis joint coupled in series to the fixed and adjuster frames, respectively.

In a similar manner, a typical method embodiment of the invention comprises the steps of coupling a carrier for each of a plurality of elements each having a pointing axis to a first universal joint of a fixed frame for each of the plurality of elements, coupling the carrier for each of the plurality of elements to a second universal joint of an adjuster frame for each of the plurality of elements offset from the first universal joint, the adjuster frame disposed substantially parallel to the fixed frame, and moving the adjuster frame relative to the fixed frame with at least one drive mechanism to produce coordinated pointing of the plurality of elements. The method may be further modified in a manner consistent with the apparatus embodiments described herein.

In another embodiment of the invention, a pointing apparatus comprises a plurality of element means for pointing, each having a pointing axis and each being attached to a carrier, a fixed frame including a first universal joint coupled to the carrier for each of the plurality of element means, an adjuster frame disposed substantially parallel to the fixed frame and including a second universal joint coupled to the carrier offset from the first universal joint for each of the plurality of element means, and at least one drive mechanism means for moving the adjuster frame relative to the fixed frame to produce coordinated pointing of the plurality of element means. The plurality of element means may comprise high concentration photovoltaic cells. This apparatus may be similarly modified consistent with the other systems or methods described herein.

### BRIEF DESCRIPTION OF THE DRAWINGS

Referring now to the drawings in which like reference numbers represent corresponding parts throughout:

FIGS. 1A & 1B illustrates pointing of a single element pointed in coordination as part of an array of elements;

FIG. 2 illustrates coordinated pointing of an array of elements;

FIG. 3 illustrates a single optical element of an exemplary embodiment of the invention;

FIG. 4 illustrates an exemplary embodiment of the invention of a plurality elements pointed in coordination;

FIGS. 5A-5D illustrates some exemplary elements that may be employed with embodiments of the invention; and

FIG. 6 is a flowchart of a method of coordinated pointing of elements according to an embodiment of the invention.

### DETAILED DESCRIPTION OF THE PREFERRED EMBODIMENT

1. Overview

The implementation of high concentration photovoltaic power systems necessitates a pointing and tracking system to point the optical elements toward the sun. The accuracy of pointing required depends on several factors related to the optical and mechanical design of the system. Under an ideal case, the optical acceptance angle is theoretically limited to θ=sin⁻¹(1/\sqrt{C}) for a three-dimensional or point-focus concentrator, where C is the concentration ratio (assumed isotropic). Thus, a concentration ratio of 500 has a maximum theoretical optical acceptance angle of approximately 2.56°, for example. However, practical design considerations require additional tolerances throughout the system that typically drive pointing requirements to much tighter tolerances (e.g., typically ±0.1°).

As detailed hereafter, embodiments of the invention can address the problems outlined above by implementing two-axis pointing of the individual photovoltaic cells/optical modules. Embodiments of the invention can reduce costs in all applications and permit more widespread use of high concentration photovoltaic solar power systems to small-scale, rooftop and portable applications.

Embodiments of the invention afford numerous advantages over conventional systems. For example, embodiments of the invention can eliminate steel structure associated with pole mounting and/or rotation of large structures of conventional solar power systems. Embodiments of the invention can also eliminate costly structure that is required with conventional systems to support higher wind loads and stiffness requirements resulting from larger, bulky structures. Embodiments of the invention can also be readily mass produced and take advantage of the economies of scale of a much higher manufacturing volume. Further, embodiments of the invention can eliminate any motion of the main structure, permitting fixed mounting installation in contrast to conventional systems. Thus, embodiments of the invention may be applied to lower cost to be more competitive with other sources of energy, and provide more widespread application to other potential solar energy market segments.

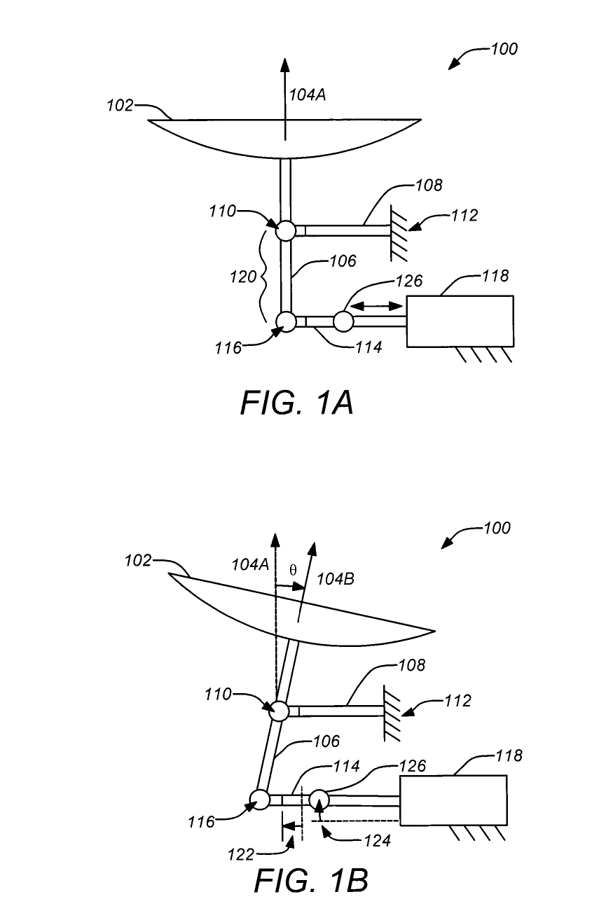

FIGS. 1A & 1B illustrates pointing of a single optical element pointed in coordination as part of an array of optical elements. FIG. 1A illustrates a side view of a single optical element 102 in a pointing system 100. The optical element 102 has a pointing axis 104A. In the case where the optical element 102 comprises a photovoltaic cell (such as a high concentration photovoltaic cell), the pointing axis 104A is directed at the sun and the pointing system 100 is designed to maintain pointing at the sun as its position in the sky changes. The optical element 102 is affixed to a carrier 106 which is used to support and manipulate the optical element 102. The carrier 106 is coupled to a fixed frame 108 through a first joint 110. The fixed frame 108 is attached to ground 112. The carrier 106 is also coupled to an adjuster frame 114 through a second joint 116. The adjuster frame 114 is coupled to a drive mechanism 118 that moves the adjuster frame 114 to manipulate pointing of the optical element 102. This is accomplished because the adjuster frame 114 is substantially parallel to the fixed frame 108 but offset 120.

It should be noted that embodiments of the invention are not only useful for pointing optical elements such as photovoltaic cells, but may be applied in any situation where multiple individual elements must be pointed in a coordinated manner. For example, antenna systems may also employ a plurality of antenna elements that require coordinated pointing as will be appreciated by those skilled in the art. Accordingly, all embodiments described herein as implemented with an optical element, may be similarly implemented with any other form of pointed element, such as a radio frequency element as will be understood by those skilled in the art.

FIG. 1B illustrates a side view of the single optical element 102 in a pointing system 100 being moved to a new pointing position. To change the pointing position of the optical element 102, the drive mechanism 118 (which is also attached to ground 112 like the fixed frame 108) moves the adjuster frame 114. In this example, the adjuster frame 114 is moved through a substantially lateral displacement 122. This displacement 122 causes the carrier 106 to pivot about the joint 110 of the fixed frame 108 (and the carrier 106 to pivot about joint 116 of the adjuster frame 114) and move the pointing axis 104A to the new pointing axis 104B. It should be noted that in order for the adjuster frame 114 to remain substantially parallel to the fixed frame 108, one or more additional joints (e.g. joint 126) may be used to couple the drive mechanism 118 to the adjuster frame 114. Those skilled in the art will recognize many different types of drive mechanisms and couplings may be used to produce the proper relative motion between the adjuster frame 114 and the fixed frame 108. For example, the precision linear motion of the drive mechanism 118 may be derived through a jack screw mechanism coupled to the adjuster frame 114 through one or more joints.

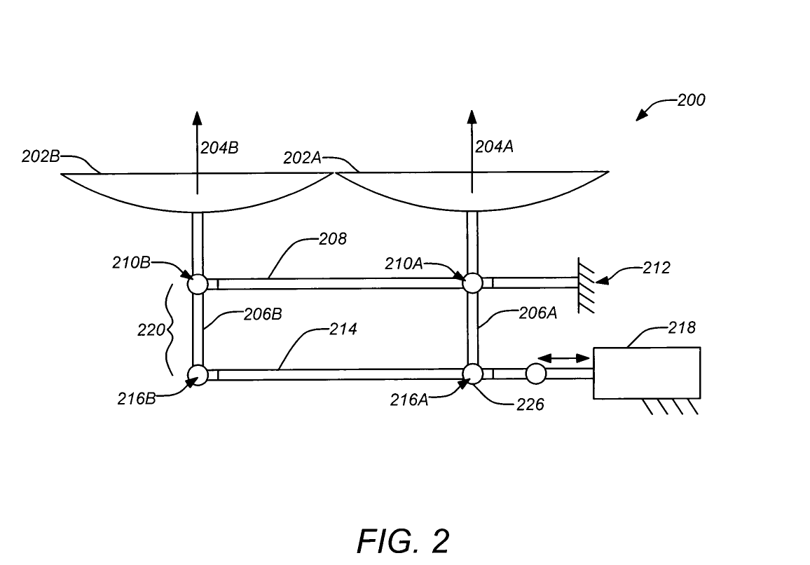

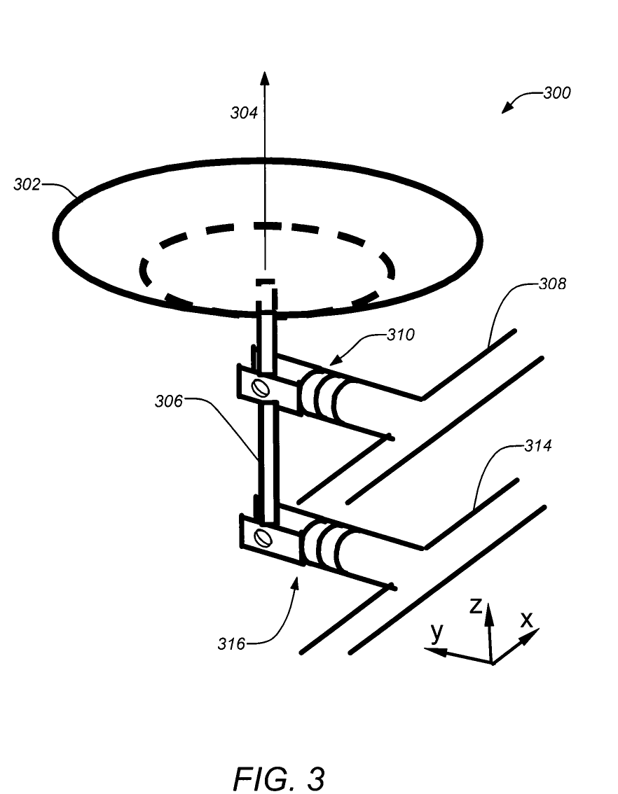

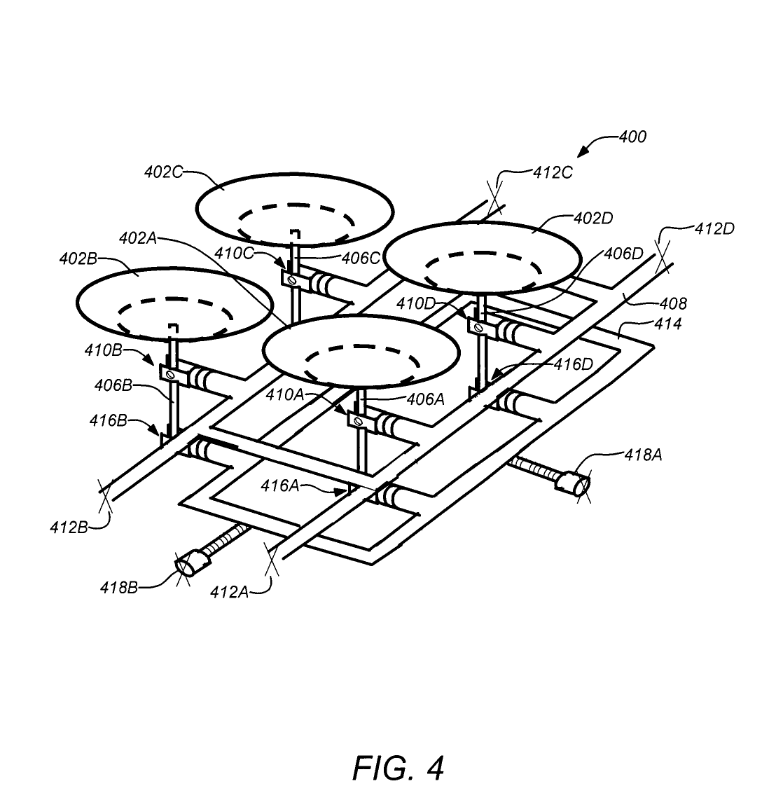

FIGS. 1A & 1B illustrate pointing of a single optical element 102 in one plane. The system 100 can be expanded to simultaneously combine pointing in a second perpendicularly intersecting plane, thus achieving three dimensional pointing control. In this case, the first and second joints 110, 116 must allow rotation in both planes simultaneously, such as provided by a universal joint, combined clevis and pinned joint, ball joint or any other known joint configuration that provides the proper coupling. This also requires either a drive mechanism controlling movement of the adjuster frame 114 in two dimensions or two single axis drive mechanisms (e.g. an azimuth drive and an elevation drive each moving the adjuster frame 114 in each plane). This three-dimensional pointing arrangement is detailed hereafter with respect to FIGS. 3 and 4. FIGS. 1A & 1B provide a detailed description of pointing for a single optical element 102 that may be used in a larger array of pointed elements as described in FIG. 2.

FIG. 2 illustrates coordinated pointing of an array of optical elements in a pointing system 200. In this case, a plurality of optical elements 202A, 202B, are each affixed to separate carriers 206A, 206B and provide separate pointing axes 204A, 204B. In this system 200, the pointing axes 204A, 204B are parallel. Coordinated pointing is achieved because both the fixed frame 208 and the adjuster frame 214 are extended from the first carrier 206A of the first optical element 202A to the second carrier 206B of the 206B second optical element. The first carrier 206A is coupled to the fixed frame 208 at the joint 210A and the second carrier 206B is coupled to the fixed frame 208 at the joint 210B. Separately, the fixed frame 208 is affixed to ground 212. Similarly, the first carrier 206A is coupled to the adjuster frame 214 at the joint 216A and the second carrier 206B is coupled to the adjuster frame 214 at the joint 216B. The substantially parallel fixed frame 208 and adjuster frame 214 separated by offset 220 sets up the coordinated pointing of the axes 204A, 204B from the common motion of the drive mechanism 218 (also attached to ground 212) coupled to the adjuster frame 214 through one or more joints 226.

Pointing of the system 200 is performed just as described for the single optical element 102 in FIG. 1B. The first optical element 202A is manipulated in a manner identical to the pointing operation of the single optical element 102 in the system 100. The extension of the fixed frame 208 and the adjuster frame 214 to be coupled to the second carrier 206B causes the same pointing changes to be applied to the second optical element 202B as well. Although the system 200 is only shown with coordinated pointing of two optical elements 202A, 202B, any number of additional optical elements coupled may be added by extending the fixed frame 208 and adjuster frame 214 and coupling additional joints in the same manner. In addition, just as with the single element system 100, pointing of the array of optical elements in a single plane can be extended to another plane (e.g. perpendicular to the plane of the page) to allow three dimensional pointing. This is described in the exemplary embodiment of a coordinated pointing system in the next section.

2. Exemplary Coordinated Pointing System for a Plurality of Elements

The elimination of inter-module tolerances permits very substantial relaxation of overall mechanical pointing accuracy. For a well-designed optical system with C=500, approximately an order of magnitude reduction in pointing accuracy is obtainable over conventional systems; a pointing accuracy requirement of ±1° to ±1.5° is permissible, compared with the ±0.1° accuracy required in conventional systems.

FIG. 3 illustrates a single optical element of an exemplary embodiment of the invention. The pointing device 300 comprises an optical element 302 (e.g., a high concentration photovoltaic cell) affixed to a carrier 306 with a collinear pointing axis 304 along the carrier 306. The fixed frame 308, attached to ground, is coupled to the carrier 306 through a first universal joint 310 (comprising a clevis joint and rotary joint). The adjuster frame 314 is offset below and substantially parallel to the fixed frame 308 and is also coupled to the carrier through a second universal joint 316 (also comprising a clevis joint and rotary joint). As shown, movement of the adjuster frame 314 in the y direction relative to the fixed frame 308 will induce rotation of the pointing axis about an axis parallel to the x axis. This is the elevation adjustment for the pointing axis 304. However, movement of the adjuster frame 314 in the x direction relative to the fixed frame 308 will induce rotation of the pointing axis about an axis parallel to the y axis. This is the azimuth adjustment for the pointing axis 304.

In the example system 300 the range of adjustment can be slightly less than 180° about each axis. However, the elevation range need only be approximately ±23° if the system 300 is mounted in a position aligned with the Earth rotation axis. Thus, the minimum height of the optical element 302 above the fixed frame is approximately D/2×sin 23° or approximately 0.2×D, where D is the diameter of the optical element 302. The system configuration allows space under the optical element 302 for cooling, e.g. via air circulation. The single optical element 302 may be employed in an array of optical elements as shown in the system 400 of FIG. 4.

FIG. 4 illustrates an exemplary embodiment of the invention of a plurality optical elements 402A-402D pointed in coordination. The system 400 comprises multiple individual optical elements 402A-402D (that are each just as the optical element 302 described in FIG. 3) are each affixed to a carrier 406A-406D in an array. In this case, the plurality of optical elements 402A-402D are arranged in a grid such that each carrier 406A-406D is coupled to both the fixed frame 408 (through a first universal joint 410A-410D) and the adjuster frame 414 (through a second universal joint 416A-416D). The fixed frame 408 is shown attached to ground at a plurality of locations 412A-412D (although only a single attachment point is necessary). Just as with the previously described embodiments, the adjuster frame 414 is offset below the fixed frame 408 and substantially parallel to it. In this system 400, the first drive mechanism 418A (an elevation drive) comprises a jack screw drive that moves the adjuster frame in the y direction to induce a rotation component about the x axis. On the other hand, a second drive mechanism 418B (an azimuth drive) comprises another jack screw drive that moves the adjuster frame in the x direction to induce a rotation component about the y axis. Each of the universal joints 410A-410D and 416A-416D comprise a clevis and a rotary joint as shown to accommodate the relative motion of the carriers 406A-406D as the adjuster frame 414 is moved relative to the fixed frame 408.

As previously mentioned, embodiments of the invention are particularly useful for photovoltaic power systems employing photovoltaic cells as the optical elements. Precision coordinated pointing afforded by embodiments of the invention is particularly beneficial to high concentration photovoltaic cells which capture sunlight from a wider area and focus it onto a smaller photovoltaic cell area. In other embodiments the optical elements may comprise individual antenna elements of an antenna array. For clarity some details inherent to any practical design as will be understood by those skilled in the art have not been shown. For example, wiring to the optical elements may be routed across one or more of the joints to the power control system. Such wiring may be conveniently routed across the joints 410A-410D to the fixed frame 414 to minimize the number of moving interfaces to be traversed.

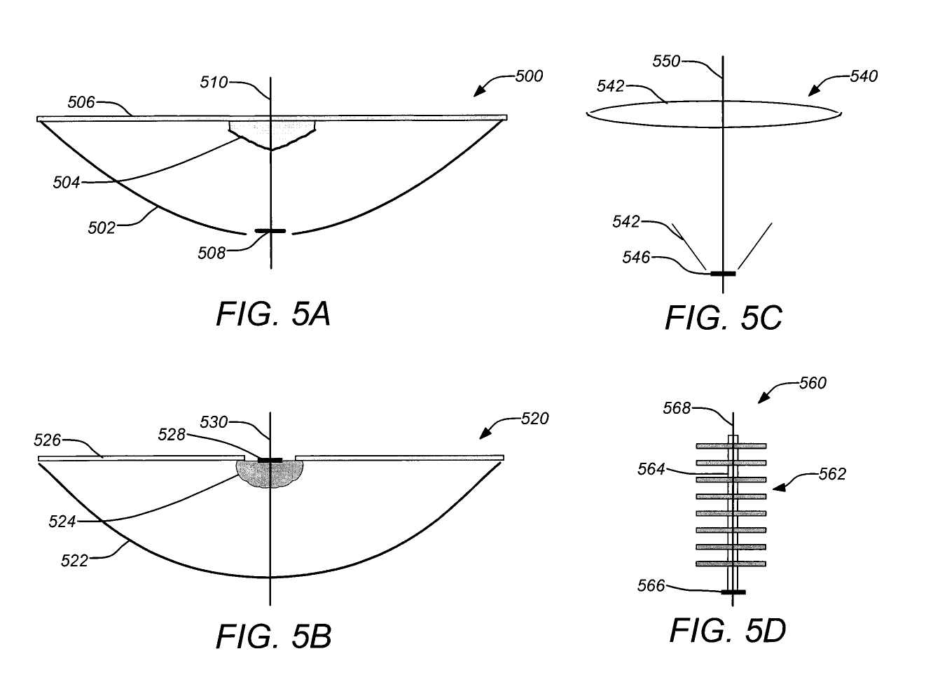

FIGS. 5A-5D illustrates some exemplary elements 500, 520, 540, 560 that may be employed with embodiments of the invention. The common quality among the exemplary optical elements 500, 520, 540 is that they all receive light from a larger area and focus it onto a photovoltaic element having a smaller area. Some further detailed examples of suitable optical elements can be found in Benitez et al., “High-Concentration Mirror Based Kohler Integrating System for Tandem Solar Cells,” and Benitez et al., “XR: A High-Performance Photovoltaic Concentrator,” which are both incorporated by reference herein.

FIG. 5A illustrates a first optical element 500 employing a primary reflector 502 and a secondary reflector 504. The pointing axis 510 is aligned with incoming light that passes through a transparent cover 506 to be reflected off the primary reflector 502 (e.g., having a parabolic surface). Light reflected from the primary reflector 502 is directed to the secondary reflector 504 which again reflects the light in a concentrated fashion onto the photovoltaic cell 508 (or receiver) at the bottom center of the primary reflector 502.

FIG. 5B illustrates another optical element 520 employing a primary reflector 522 and a secondary refractor 524. The pointing axis 530 is aligned with incoming light that passes through a transparent cover 526 to be reflected off the primary reflector 522 (e.g., having a parabolic surface). Light reflected from the primary reflector 522 is directed to the secondary refractor 524 which focuses the reflected light directly onto the lower surface of the photovoltaic cell 528 (or receiver) at the top center of the optical element 520. In this case, the active surface of the photovoltaic cell 528 is facing down to receive the refracted light.

FIG. 5C illustrates another optical element 540 employing a primary refractor 542 and a secondary reflector 544. The pointing axis 550 is again aligned with incoming light. Here that is refracted directly by the primary refractor 542 to be reflected off the secondary reflector 544 (e.g., having a conical surface). Light reflected from the secondary reflector 544 is then directed to the photovoltaic cell 546 (or receiver) at the bottom center of the secondary reflector 544. In some cases, it may be possible to implement a similar optical element without the secondary reflector 544.

FIG. 5D illustrates an antenna element 560 that can be employed in an antenna embodiment. The antenna element 560 may comprise a known phased array YAGI-type or any other suitable antenna element that is directional. Here, the pointing axis 568 is aligned in the desired pointing direction (for either receiving or transmitting). In this example, the antenna element comprises multiple directors 562 (e.g., that may be circular conductive discs) isolated from one another by an insulating boom 564. A reflector/collector element 566 is disposed at the bottom end. Selection and/or sizing of antenna elements to incorporate in an embodiment of the invention may be readily performed by those skilled in the art.

Embodiments of the invention can be operated to economically point a small opto-mechanical system to the modest accuracy and angular rate required for sun tracking. In contrast to conventional photovoltaic pointing systems, embodiments of the present invention can eliminate mass movement of the entire array as a single unit. In addition, embodiments of the invention can permit a fixed installation.

3. Method of Coordinating Pointing of a Plurality of Elements

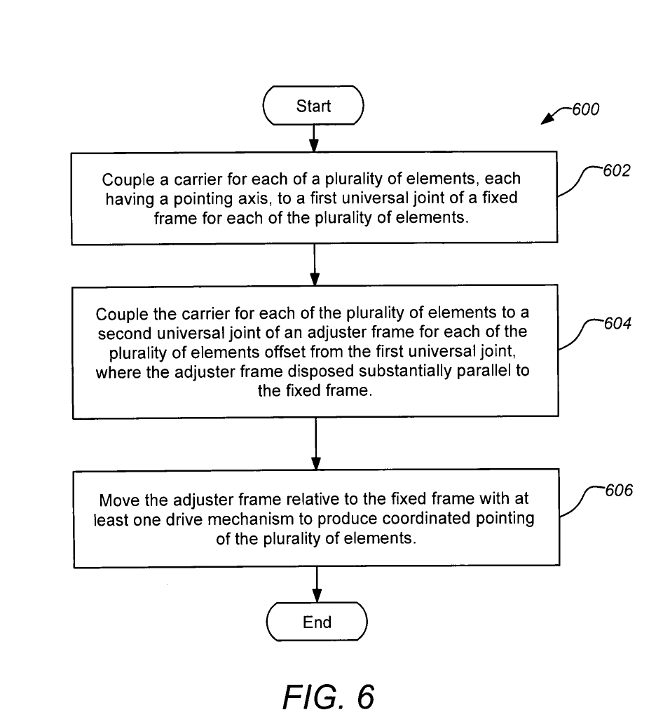

FIG. 6 is a flowchart of an exemplary method 600 of coordinating pointing of a plurality of elements. The method 600 begins with a first operation 602 of coupling a carrier for each of a plurality of optical elements each having a pointing axis to a first universal joint of a fixed frame for each of the plurality of optical elements. Next in operation 604, the carrier for each of the plurality of optical elements is coupled to a second universal joint of an adjuster frame for each of the plurality of optical elements offset from the first universal joint, where the adjuster frame disposed substantially parallel to the fixed frame. Finally in operation 606, the adjuster frame is moved relative to the fixed frame with at least one drive mechanism to produce coordinated pointing of the plurality of optical elements. The method 600 may be further modified consistent with the apparatus and systems described herein.

This concludes the description including the preferred embodiments of the present invention. The foregoing description including the preferred embodiment of the invention has been presented for the purposes of illustration and description. It is not intended to be exhaustive or to limit the invention to the precise forms disclosed. Many modifications and variations are possible within the scope of the foregoing teachings. Additional variations of the present invention may be devised without departing from the inventive concept as set forth in the following claims.

What is claimed is:

1. An apparatus for coordinated pointing, comprising:
a plurality of elements each having a pointing axis and each being attached to a carrier;
a fixed frame including a first universal joint coupled to the carrier for each of the plurality of elements;
an adjuster frame disposed substantially parallel to the fixed frame and including a second universal joint coupled to the carrier offset from the first universal joint for each of the plurality of elements; and
at least one drive mechanism to move the adjuster frame relative to the fixed frame to produce coordinated pointing of the plurality of elements.

2. The apparatus of claim 1, wherein the plurality of elements comprise photovoltaic cells in a solar power system.

3. The apparatus of claim 2, wherein the solar cells comprise high concentration photovoltaic cells.

4. The apparatus of claim 1, wherein the plurality of elements comprise antenna elements in an antenna array.

5. The apparatus of claim 1, wherein the fixed frame is disposed between the adjuster frame and the plurality of elements.

6. The apparatus of claim 1, wherein the carrier comprises a rod coupled to both the first universal joint and the second universal joint and substantially parallel to the pointing axis.

7. The apparatus of claim 1, wherein the at least one drive mechanism comprises an azimuth drive and an elevation drive.

8. The apparatus of claim 7, wherein the azimuth drive and the elevation drive each comprise a jack screw.

9. The apparatus of claim 1, wherein the first universal joint and the second universal joint each comprise a rotary joint and a clevis joint coupled in series to the fixed frame and the adjuster frame, respectively.

10. A method of coordinated pointing, comprising the steps of:
coupling a carrier for each of a plurality of elements each having a pointing axis to a first universal joint of a fixed frame for each of the plurality of elements;
coupling the carrier for each of the plurality of elements to a second universal joint of an adjuster frame for each of the plurality of elements offset from the first universal joint, the adjuster frame disposed substantially parallel to the fixed frame; and
moving the adjuster frame relative to the fixed frame with at least one drive mechanism to produce coordinated pointing of the plurality of elements.

11. The method of claim 10, wherein the plurality of elements comprise photovoltaic cells in a solar power system.

12. The method of claim 11, wherein the solar cells comprise high concentration photovoltaic cells.

13. The method of claim 10, wherein the plurality of elements comprise antenna elements in an antenna array.

14. The method of claim 10, wherein the fixed frame is disposed between the adjuster frame and the plurality of elements.

15. The method of claim 10, wherein the carrier comprises a rod coupled to both the first universal joint and the second universal joint and substantially parallel to the pointing axis.

16. The method of claim 10, wherein the at least one drive mechanism comprises an azimuth drive and an elevation drive.

17. The method of claim 16, wherein the azimuth drive and the elevation drive each comprise a jack screw.

18. The method of claim 10, wherein the first universal joint and the second universal joint each comprise a rotary joint and a clevis joint coupled in series to the fixed frame and the adjuster frame, respectively.

19. An apparatus for coordinated pointing, comprising:
a plurality of element means for pointing, each having a pointing axis and each being attached to a carrier;
a fixed frame including a first universal joint coupled to the carrier for each of the plurality of element means;
an adjuster frame disposed substantially parallel to the fixed frame and including a second universal joint coupled to the carrier offset from the first universal joint for each of the plurality of element means; and
at least one drive mechanism means for moving the adjuster frame relative to the fixed frame to produce coordinated pointing of the plurality of element means.

20. The apparatus of claim 19, wherein the plurality of element means comprise high concentration photovoltaic cells.
